(19) United States
(12) Patent Application Publication
(10) Pub. No.: US 2012/0266959 A1
(43) Pub. Date: Oct. 25, 2012

(54) SEMICONDUCTOR ELECTRODE FOR DYE-SENSITIZED SOLAR CELL, METHOD OF MANUFACTURING THE SAME, AND DYE-SENSITIZED SOLAR CELL HAVING THE SAME

(75) Inventors: Byungyou Hong, Suwon (KR); Hyung Jin Kim, Suwon (KR); Minjae Shin, Suwon (KR); Ju Mi Kim, Deajeon (KR)

(73) Assignee: Sungkyunkwan University Foundation for Corporate Collaboration, Suwon (KR)

(21) Appl. No.: 13/273,560

(22) Filed: Oct. 14, 2011

(30) Foreign Application Priority Data
Apr. 19, 2011 (KR) 10-2011-0036325

(51) Int. Cl. H01L 31/0224; H01L 31/18; B82Y 30/00

(52) U.S. Cl. 136/263; 438/82; 977/734; 977/762; 977/773; 257/E31.124

(57) ABSTRACT

A semiconductor electrode for a dye-sensitized solar cell, a method of manufacturing the semiconductor electrode, and a dye-sensitized solar cell having the semiconductor electrode are provided which can prevent electrons from being transported to an electrolyte from the surface of the semiconductor electrode to raise photocurrent and photovoltage and to improve an energy conversion efficiency by forming a semiconductor oxide layer on a conductive substrate, forming an organic layer in a core-shell structure thereon, and adsorbing a dye on the organic layer through the use of an electrostatic attraction.

### CROSS-REFERENCE TO RELATED APPLICATIONS

This application claims the benefit of Korean Patent Application No. 10-2011-0036325, filed with the Korean Intellectual Property Office on Apr. 19, 2011, the disclosure of which is incorporated herein by reference in its entirety.

### BACKGROUND

1. Field of the Invention

The present invention relates to a semiconductor electrode for a dye-sensitized solar cell, a method of manufacturing the semiconductor electrode, and a dye-sensitized solar cell having the semiconductor electrode, and more particularly, to a semiconductor electrode for a dye-sensitized solar cell which can prevent electrons from being transported to an electrolyte from the surface of the semiconductor electrode to raise photocurrent and photovoltage and to improve an energy conversion efficiency by forming a semiconductor oxide layer on a conductive substrate, forming an organic layer in a core-shell structure thereon, and adsorbing a dye on the organic layer through the use of an electrostatic attraction, a method of manufacturing the semiconductor electrode, and a dye-sensitized solar cell having the semiconductor electrode.

2. Description of the Related Art

A dye-sensitized solar cell is a photo-electrochemical solar cell including as main constituent elements photosensitive dye molecules that can absorb visible light to generate electron-hole pairs and transition metal oxide that transports the generated electrons, unlike known silicone solar cells using p-n junctions. A representative example of a known dye-sensitized solar cell is disclosed by Gratzel et al. of Swiss (see U.S. Pat. Nos. 4,927,721 and 5,350,644). The dye-sensitized solar cell disclosed by Gratzel et al. includes a semiconductor electrode formed of nano-particles of titanium dioxide (TiO₂) coated with dye molecules, a counter electrode coated with platinum or carbon, and an electrolyte solution enclosed between the electrodes. The dye-sensitized solar cell has much attention as a future solar cell, since it is excellent in characteristics such as low cost, environmental friendliness, transparency, and coloration, can retain an efficiency at an inclination angle and with low light intensity, and it can be manufactured in various forms.

Many problems should be solved in mass production and practical use of the dye-sensitized solar cell. For example, the low electron density due to recombination of electrons in the interface between titanium dioxide and an electrolyte or the interface between titanium dioxide and a conductive substrate, the low density of a dye adsorbed on the surface of titanium dioxide, and the weak chemical bond of titanium dioxide and a dye cause a low efficiency and low long-term stability of the dye-sensitized solar cell. Therefore, it has been raised as an important problem that the electric conductivity of the semiconductor electrode should be improved to enhance the photoelectric efficiency of a solar cell by reducing a direct contact part with an electrolyte to suppress the inverse reaction of electrons.

### SUMMARY

An advantage of some aspects of the invention is that it provides a semiconductor electrode for a dye-sensitized solar cell which can raise photocurrent and photovoltage to enhance an energy conversion efficiency by preventing electrons from being transported to an electrolyte from the surface of a semiconductor oxide layer or the surface of a conductive substrate and preventing recombination of electrons between the surface of the electrode and the electrolyte.

Another advantage of some aspects of the invention is that it provides a method of manufacturing the above-mentioned semiconductor electrode.

Still another advantage of some aspects of the invention is that it provides a high-efficiency dye-sensitized solar cell having the above-mentioned semiconductor electrode.

According to an aspect of the invention, there is provided a semiconductor electrode for a dye-sensitized solar cell including: a conductive substrate; a semiconductor oxide layer that is formed on the conductive substrate; an organic layer with which the surface of the semiconductor oxide layer and the surface of the conductive substrate are coated in a core-shell structure; and a dye that is adsorbed on the surface of the organic layer.

The conductive substrate may be a glass substrate or a plastic substrate coated with indium tin oxide (ITO), fluorine-doped tin oxide (FTO), or carbon nano-tube (CNT).

The semiconductor oxide layer may be formed in the form of nano-particle, nano-wire, or nano-tube and the semiconductor oxide layer may be formed of one or more selected from the group consisting of titanium oxide, tungsten oxide, niobium oxide, hafnium oxide, indium oxide, tin oxide, and zinc oxide.

The surface of the semiconductor oxide layer formed on the conductive substrate and the surface of the conductive substrate not covered with the semiconductor oxide layer may be coated with the organic layer in a core-shell structure. The organic layer may be formed of a silane compound and the silane compound may be aminopropyltriethoxysilane (APS).

The dye adsorbed on the organic layer may be a ruthenium complex.

According to another aspect of the invention, there is provided a high-efficiency dye-sensitized solar cell including: the semiconductor electrode; an electrolyte layer; and a counter electrode.

According to still another aspect of the invention, there is provided a method of manufacturing a semiconductor electrode for a dye-sensitized solar cell, the method including: (S1) forming a semiconductor oxide layer on a conductive substrate; (S2) dipping the conductive substrate having the semiconductor oxide layer formed thereon in a solution including an organic material to coat the surface of the semiconductor oxide layer and the surface of the conductive substrate with an organic layer in a core-shell structure; and (S3) adsorbing a dye on the organic layer through the use of an electrostatic attraction.

In S1, the semiconductor oxide layer may be formed in the form of nano-particle, nano-wire, or nano-tube.

The method of manufacturing a semiconductor electrode for a dye-sensitized solar cell may further include drying the conductive substrate having the semiconductor oxide layer formed thereon in the temperature range of 50° C. to 150° C. and then sintering the resultant in the temperature range of 100° C. to 1000° C. after S1.

In S2, the concentration of the organic material may be controlled to enhance the efficiency of the dye-sensitized solar cell. Particularly, when the organic material is aminopropyltriethoxysilane, the concentration of the aminopropyltriethoxysilane may be in the range of 0.2 to 200 mM.

According to the aspects of the invention, since the surface of the semiconductor oxide layer coming in direct contact with an oxidation/reduction electrolyte and the surface of the conductive substrate not covered with the semiconductor oxide layer in the dye-sensitized solar cell are coated with the organic layer in a core-shell structure, it is possible to block an electron loss path in the course of transporting electrons generated by light to an external circuit and thus to markedly enhance the energy conversion efficiency. It is also possible to manufacture a high-efficiency dye-sensitized solar cell through the use of a simple manufacturing process such as a dip coating method without using high-cost equipment.

### BRIEF DESCRIPTION OF THE DRAWINGS

FIGS. 1A and 1B are diagrams illustrating the structure of a dye-sensitized solar cell having a semiconductor electrode according to an embodiment of the invention and the function of a core-shell structure in the embodiment of the invention, respectively.

FIG. 2 is a diagram schematically illustrating a flow of processes of manufacturing the dye-sensitized solar cell having the semiconductor electrode according to the embodiment of the invention.

FIG. 3 is a graph illustrating the J-V characteristics of the dye-sensitized solar cell with a variation in concentration of an organic material.

FIG. 4 is a graph illustrating a variation in impedance of the dye-sensitized solar cell with the variation in concentration of the organic material.

FIG. 5 is a diagram illustrating UV spectra of a glass substrate coated with an organic material produced in Example 1-3 and a TiO₂ electrode coated with the organic material.

FIG. 6 is a diagram illustrating an FT-IR spectrum of the semiconductor electrode manufactured by changing the concentration of the organic material.

FIG. 7 is a transmission electron microscope (TEM) photograph of the semiconductor electrode manufactured in Example 1-3.

FIGS. 8A to 8E are diagrams illustrating TOF-SIMS data obtained by measuring variations of elements with the variation in concentration of the organic material.

### DESCRIPTION OF EXEMPLARY EMBODIMENTS OF THE INVENTION

Hereinafter, the invention will be described in detail with reference to the accompanying drawings.

A semiconductor electrode for a dye-sensitized solar cell according to the invention includes: a conductive substrate; a semiconductor oxide layer formed on the conductive substrate; an organic layer with which the surface of the semiconductor oxide layer and the surface of the conductive substrate are coated in a core-shell structure; and a dye adsorbed on the surface of the organic layer.

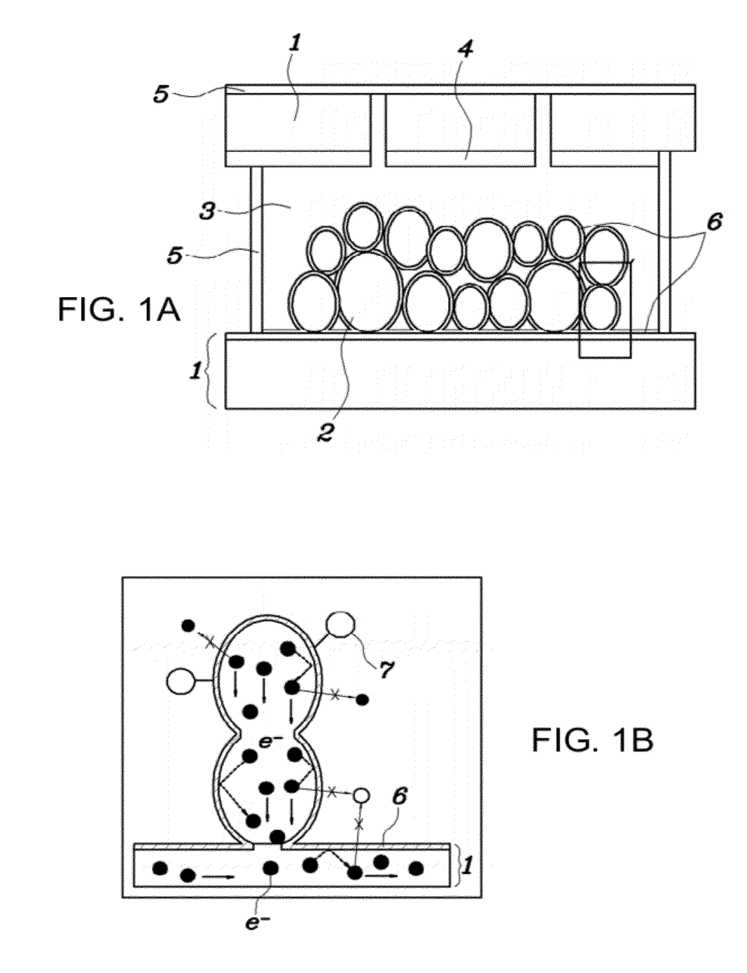

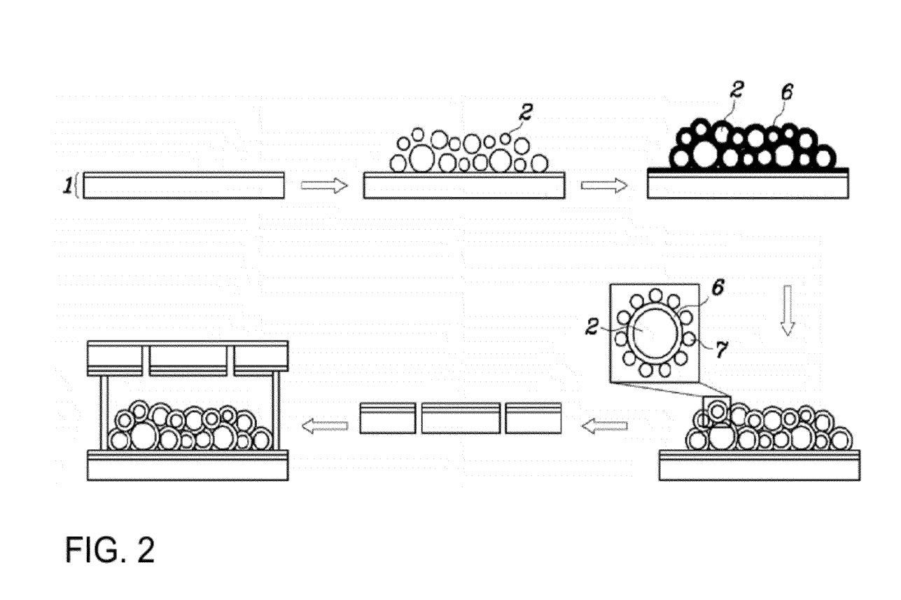

FIGS. 1A and 1B are sectional views schematically illustrating the configuration of a dye-sensitized solar cell having a semiconductor electrode according to an embodiment of the invention. The semiconductor electrode according to the embodiment of the invention includes a conductive substrate 1, a semiconductor oxide layer 2, an organic layer 6 with which the conductive substrate 1 and the semiconductor oxide layer 2 are coated in a core-shell structure, and a dye 7 adsorbed on the organic layer 6.

In the semiconductor electrode, the semiconductor oxide layer 2 is formed on the conductive substrate 1. The conductive substrate can employ a glass substrate or a plastic substrate coated with indium tin oxide (ITO), fluorine-doped tin oxide (FTO), or the like, but is not limited to these.

In the semiconductor electrode, the semiconductor oxide layer 2 can be formed of one or more selected from the group consisting of titanium oxide, tungsten oxide, niobium oxide, hafnium oxide, indium oxide, tin oxide, and zinc oxide, but is not limited to these. The semiconductor oxides can be used alone or in combination of two or more. Preferable examples of the semiconductor oxide include TiO₂, SnO₂, ZnO, WO₃, Nb₂O₅, and TiSrO₃ and TiO₂ is particularly preferable.

It is preferable that the semiconductor oxide layer 2 have an increased surface area to improve the degree of adsorption to an electrolyte layer. Therefore, it is preferable that the semiconductor oxide layer have a nano structure such as a nano-tube, a nano-wire, a nano-belt, or a nano-particle. The forms of the nano-particle, the nano-wire, and the nano-tube are more preferable.

In the semiconductor electrode according to this embodiment, the surface of the semiconductor oxide layer and the surface of the conductive substrate, that is, the surface of the conductive substrate not covered with the semiconductor oxide layer, are coated with the organic layer 6 in a core-shell structure. FIG. 1B is a diagram schematically illustrating the function of the core-shell structure in the invention. In the typical operating principle of the dye-sensitized solar cell, dye molecules chemically adsorbed on the surface of the nano-particle semiconductor oxide electrode generate electron-hole pairs when they absorb solar light (visible light), the electrons are injected into the conduction band of the semiconductor oxide. The electrons injected into the semiconductor oxide electrode are transported to a transparent conductive film via interfaces between nano particles to generate current. The holes generated from the dye molecules receive electrons from the oxidation-reduction electrolyte and are reduced, whereby the operation of the dye-sensitized solar cell is completed. As can be seen From FIG. 1B, when the surface of the conductive substrate and the surface of the semiconductor oxide layer are coated with the organic layer, the electron-transport ability from the dye to the semiconductor oxide is lowered due to the organic layer, but it is rather possible to effectively prevent the electron loss in the interface between the conductive substrate and the electrolyte and in the interface between the semiconductor oxide layer and the electrolyte, thereby enhancing the total efficiency.

In the semiconductor electrode according to the invention, the dye 7 absorbing light is adsorbed on the organic layer 6. The coated organic material exhibits (+) electricity on the surface of the semiconductor oxide and the adsorbed dye exhibits (−) electricity due to a carboxyl group. Accordingly, the density of the dye can be raised through the use of the electrostatic attraction, thereby improving the long-term stability of the final dye-sensitized solar cell.

In the invention, the dye 7 can employ dyes which are typically used in the field of solar cells. A ruthenium complex can be preferably used. The dye is not particularly limited, as long as it has a charge separating function and performs a photosensitive operation. In addition to the ruthenium complex, examples of the dye include xanthine dyes such as rhodamine B, rose bengal, eosin, and erythrocin, cyanine dyes such as quinocyanine and kryptocyanine, basic dyes such as phenosafranine, calbee blue, thiosine, and methylene blue, porphyrin compounds such as chlorophyll, zinc porphyrin, and magnesium prophyrin, other azo dyes, phthalocyanine compounds, complex compounds such as ruthenium, anthraquinone dyes, and polycyclic quinine dyes. These examples can be used alone or in a combination of two or more. RuL₂(SCN)₂, RuL₂(H₂O)₂, RuL₃, RuL₂, and the like can be used as the ruthenium complex (where L represents 2,2′-bipyridyl-4,4′-dicarboxylate or the like).

The invention provides a method of manufacturing the semiconductor electrode. The important technique feature of the method according to the invention is to coat the surface of the semiconductor oxide layer and the surface of the conductive substrate with the organic layer before adsorbing the dye. Due to the presence of the organic layer, it is possible to effectively prevent the loss of electrons into the electrolyte.

The method of manufacturing a semiconductor electrode for a dye-sensitized solar cell according to the invention will be described in detail below by steps.

First, a semiconductor oxide layer is formed on a conductive substrate (step S1).

The method of forming the semiconductor oxide layer on the conductive substrate is not particularly limited, but a method of forming the semiconductor oxide in a nano structure can be preferably used in consideration of physical properties, convenience, and cost. A method of preparing a paste in which nano-structure semiconductor oxide powder is homogeneously dispersed in an appropriate solvent and coating the conductive substrate with the paste can be preferably used. Typically-known coating methods such as a spraying method, a spin coating method, a dipping method, a printing method, a doctor blade method, and a sputtering method can be used as the coating method.

When the semiconductor oxide layer is formed using the coating method, drying and sintering steps should be performed after the coating is finished, as known well in the related art. The drying step may be performed in the temperature range of about 50° C. to 150° C. and the sintering step may be performed in the temperature range of about 100° C. to 1000° C. Depending on the type of the substrate to be used, it can be determined whether the sintering step should be performed and the temperatures of the drying step and the sintering step can be also determined.

Thereafter, the substrate having the semiconductor oxide layer formed thereon is dipped in a solution including an organic material and the surface of the semiconductor oxide layer and the surface of the conductive substrate are coated with an organic layer in a core-shell structure (step S2).

This method is called a “dip coating method”, in which the overall surface to be coating is dipped in a solution in which an organic material is dispersed in a solvent for about 10 to 60 minutes. A preferable dipping time is 30 minutes. This coating method can greatly reduce the time and cost necessary for the manufacturing of a dye-sensitized solar cell with a very simple process. Examples of the solvent used to disperse the organic material in the invention include pentane, hexane, benzene, toluene, xylene, dichloromethane, and chloroform, but the solvent is not limited to these examples. Since the solvent affects the photoelectric efficiency of the finally-obtained solar cell, it is necessary to select a solvent suitable for an organic material to be used.

In step S2, the concentration of the organic material can be controlled to enhance the efficiency of the dye-sensitized solar cell. When the organic material is aminopropyltriethoxysilane (APS), the concentration of the aminopropyltriethoxysilane is preferably in the range of 0.2 to 200 mM and more preferably about 20 mM. The content of silicon (Si) which is a main component of the organic material is changed depending on the concentration of the organic material. The surface of the semiconductor oxide photoelectrode coated with the organic material exhibits the (+) electricity and the dye adsorbed on the organic layer exhibits the (−) electricity due to a carboxyl group. The increase in amount of the organic material causes an increase in amount of the dye to be adsorbed on the semiconductor oxide photoelectrode through the use of the electrostatic attraction, thereby improving the electrical characteristics. When the concentration of the organic material is less than 0.2 mM, the organic layer is ineffective. When the concentration of the organic material is greater than 200 mM, the organic layer serves as a resistor interfering with the movement of electrons.

Finally, the dye is adsorbed on the surface of the organic layer through the use of the electrostatic attraction (step S3). By the use of methods widely known in the related art, the substrate produced in step S2 is dipped in a solution including a photosensitive dye for 12 hours or more, preferably for 24 hours, to adsorb the dye on the surface of the semiconductor oxide layer and the resultant is washed with a solvent such as ethanol and acetonitrile to remove the remainder.

The invention provides a dye-sensitized solar cell having the semiconductor electrode according to the invention. Referring to FIG. 1A, the dye-sensitized solar cell according to the invention includes the semiconductor electrode according to the invention, a counter electrode 4, and an electrolyte 3 filled therebetween. Known materials can be all used as the materials of the counter electrode and the electrolyte used in the invention. Examples of the material of the counter electrode include platinum, gold, carbon, carbon nano-tube, and grapheme. Examples of the electrolyte include liquid electrolytes such as an acetonitrile solution of iodine and 3-methoxypropionitrile or solid electrolytes such as triphenylmethane, carbazole, N,N′-diphenyl-N,N′-bis((3-methylphenyl)-1,1′-biphenyl)-4,4′-diamine (TPD), but the electrolyte is not limited to these examples.

The method of manufacturing the dye-sensitized solar cell according to the invention having the above-mentioned structure is not particularly limited and any method known in the related art can be used without any limitation. For example, when a solar cell is manufactured using the semiconductor electrode according to the invention, the semiconductor electrode and the counter electrode are disposed to face each other, a space in which an electrolyte layer is enclosed is formed using a predetermined sealing material 5, and an electrolyte is injected into the space, through the use of the methods widely known in the related alt. The transparent electrode and the counter electrode can be bonded with an adhesive such as a thermoplastic polymer film (such as SURLYN (made by Dupont), an epoxy resin, or a UV-curable agent. The thermoplastic polymer film is located between two electrodes and are then heated, pressed, and sealed.

The invention will be described in more detail below with reference to examples. The examples are intended only to explain the invention but should not be considered to limit the scope of the invention.

### Examples 1-1 to 1-4 and Comparative Example 1

### Manufacturing of Semiconductor Electrode

### Example 1-1

Fluorine-coated tin oxide (FTO) is applied in a thickness of 200 nm onto a glass substrate (2 cm×2 cm) by the use of a sputtering apparatus, a paste of semiconductor oxide (TiO₂) powder with a particle size of 13 nm is applied thereon using a doctor blade method, and the resultant is dried at 100° C. for 10 minutes. The dried resultant is input to an electric furnace, the temperature is raised at 5° C./min in the atmosphere, and the resultant is sintered at 600° C. for 70 minutes, whereby a conductive substrate formed of TiO₂ nano particles with a particle diameter of 14 to 37 nm is obtained. The substrate is dipped in a solution in which 2.4 μL of an aminopropyltriethoxysilane (APS) solution made by Sigma-Aldrich Corporation is dispersed in 50 mL of toluene for 30 minutes to coat the substrate with an aminopropyltriethoxysilane layer. Thereafter, the substrate coated with the aminopropyltriethoxysilane layer dipped in a solution of Ru photosensitive dye N719 made by Solaronix SA for 24 hours and the resultant is dried to adsorb the dye on the surface of the TiO₂ layer and the surface of the conductive substrate. The resultant is washed with ethanol to wash out the dye not adsorbed but remaining on the TiO₂ layer after the adsorption of the dye is finished, and the resultant is dried, whereby a semiconductor electrode is manufactured.

### Example 1-2

A semiconductor electrode is manufactured in the same way as in Example 1-1, except that a solution in which 24 aμL of the aminopropyltriethoxysilane (APS) solution is dispersed in 50 mL of toluene.

### Example 1-3

A semiconductor electrode is manufactured in the same way as in Example 1-1, except that a solution in which 240 μL of the aminopropyltriethoxysilane (APS) solution is dispersed in 50 mL of toluene.

### Example 1-4

A semiconductor electrode is manufactured in the same way as in Example 1-1, except that a solution in which 2400 μL of the aminopropyltriethoxysilane (APS) solution is dispersed in 50 mL of toluene.

### Comparative Example 1

A semiconductor electrode is manufactured in the same way as in Example 1-1, except that the organic material coating step is not performed.

### Example 2 and Comparative Example 2

### Manufacturing Dye-Sensitized Solar Cell

### Example 2

The surface of a glass substrate coated with PTO is coated with platinum to manufacture a counter electrode. The counter electrode as a positive electrode and the semiconductor electrode obtained in Examples 1-1 to 1-4 as a negative electrode are assembled. When both electrodes are assembled, the conductive surfaces of the positive electrode and the negative electrode face the interior of the cell so that the platinum layer and the metal oxide layer face each other. Then, Melting sheety SX 1170 60 μm made by Solaronix SA is interposed between two electrodes and two electrodes are closely pressed to each other under about 2 atm on a heating plate of 120° C. An electrolyte solution is filled in the space between two electrodes, whereby the dye-sensitized solar cell according to the invention is obtained. At this time, an electrolyte solution Iodolyte AN-50 made by Solaronix Sa is used as the electrolyte solution.

### Comparative Example 2

A dye-sensitized solar cell is manufactured in the same way as in Example 2, except that the semiconductor electrode obtained in Comparative Example 1 is used.

### Experimental Example 1

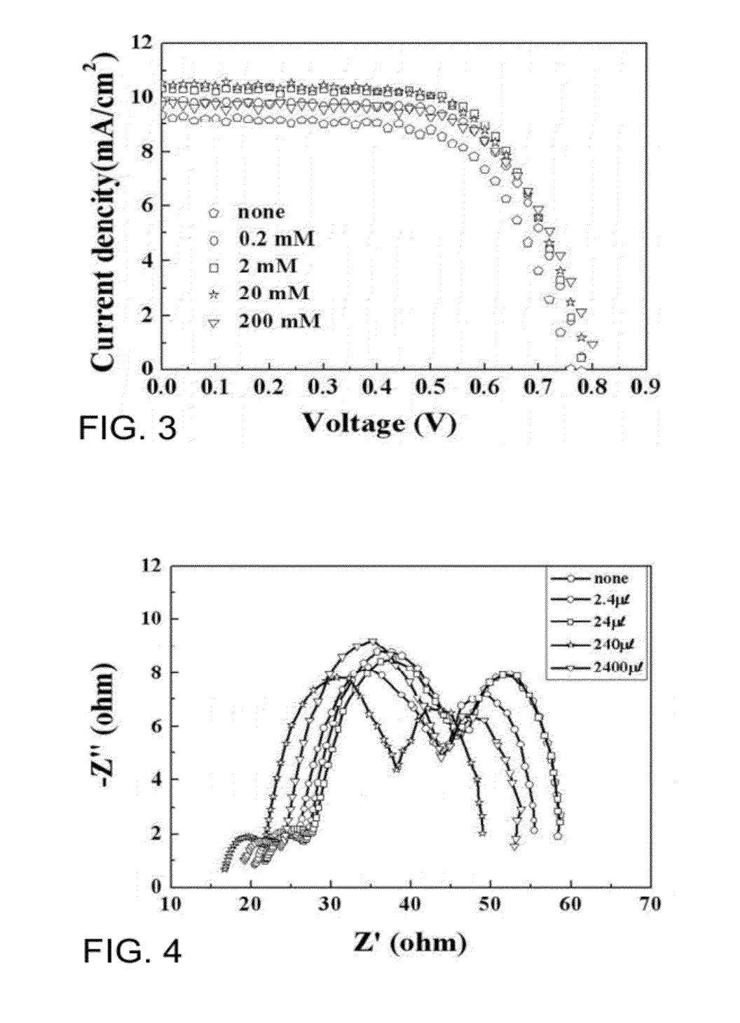

In the dye-sensitized solar cells having the semiconductor electrodes manufactured in Examples 1-1 to 1-4, a current density with a variation in voltage is measured and the measurement results are shown in FIG. 3. Parameters of the dye-sensitized solar cell by the concentrations of the coating organic material are calculated and shown in table 1.

J_{sc} (short-circuit current density) represents the current per unit area when a bias voltage is not applied to a solar cell. This is caused by the natural movement of current generated in a cell reaction. When the bias voltage is made to increase in the manufactured solar cell, the current value gradually decreases and the current does not flow finally. This voltage is defined as V_{oc} (open-circuit voltage). J_{sc} increases as the amount of the dye adsorbed on semiconductor particles increases. It is preferable that the bonding property between particles of the semiconductor electrode be excellent and the semiconductor structure have no defective structure. J_{sc} also increases as pores among the particles well communicate with each other. The maximum electromotive force expressed by V_{oc} is determined depending on the difference between the oxidation-reduction potential of the electrolyte and the Fermi level of the semiconductor electrode. Theoretically, the maximum electromotive force is a constant when the same electrolyte and the same photoelectrode are used. However, electrons are lost due to a phenomenon that electrons are recombined with the electrolyte and the dye while photoelectrons excited in the dye are moving to TCO, a phenomenon that the conduction band energy level on the surface of the photoelectrode on which the dye is adsorbed is shifted down, and the like. FF (Fill Factor) is an indicator indicating the excellence of a device manufacturing process and exhibits a higher value as the resistance of the electrode becomes smaller. FF becomes higher as the I-V curve gets closer to a rectangle. FF is defined as a value obtained by dividing the area of an inscribed rectangle by the area of a circumscribed rectangle in a voltage/current curve.

The solar cell efficiency η is defined as a ratio of the output of the solar cell to the optical energy incident on a unit area. The output of the solar cell is defined as a value by multiplying the open-circuit voltage V_{oc}, the short-circuit current density J_{sc}, and the fill factor FF.

$$η = \frac{{V}_{oc} \cdot {J}_{sc} \cdot FF}{{P}_{input}} \times 100 ( \% )$$

A solar simulator (made by Abet Techonolgies, 300 W Xe lamp AM 1.5) is used to measure the photoelectric conversion efficiency.

TABLE 1

| | Photoelectric | | | |
|---|---|---|---|---|
| | conversion | Open-circuit | J_{sc} | Fill Factor |
| Classification | efficiency (%) | voltage (V) | (mA/cm²) | (%) |
| Comparative | 4.37 | 0.75 | 9.10 | 63.5 |
| Example 1 | | | | |
| Example 1-1 | 4.98 | 0.78 | 9.89 | 64.4 |
| Example 1-2 | 5.28 | 0.78 | 10.42 | 64.8 |
| Example 1-3 | 5.20 | 0.79 | 10.57 | 62.1 |
| Example 1-4 | 4.96 | 0.81 | 9.82 | 62.3 |

In the photoelectrode according to the invention, it can be seen from Table 1 that the coating with the organic layer serves to reduce the recombination probability in TiO₂ and the electrolyte to reduce the electron loss of the conduction band of TiO2 and to derive an increase in J_{sc}, J_{sc} increases up to the Fermi energy of TiO₂, and thus J_{oc} increases. As a result, it can be seen that the photoelectric conversion efficiency in Examples 1-1 to 1-4 increases by about 13.5% to 20.8%, compared with Comparative Example 1.

### Experimental Example 2

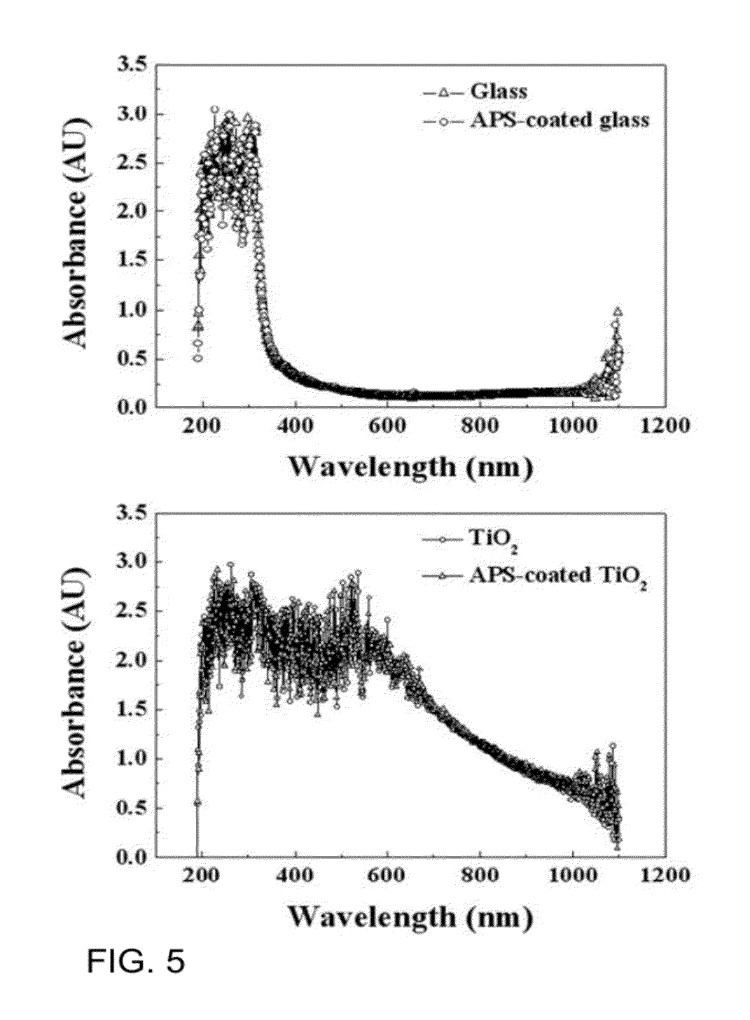

In the dye-sensitized solar cells having the semiconductor electrodes manufactured in Examples 1-1 to 1-4, the variation in impedance of the dye-sensitized solar cell with a variation in concentration of the solution including the organic material is measured and the results are shown in FIG. 4 and table 2. The measurement of the variation in impedance of a dye-sensitized solar cell is very useful for the study of a charge moving speed. The measurement provides information on the resistance of a transparent work electrode, the interfacial resistance between the transparent work electrode and an oxide electrode, the resistance of the oxide electrode, the interfacial resistance between the oxide layer and the electrolyte, and the interfacial resistance between the counter electrode and the electrolyte.

TABLE 2

| Classifi- | Comparative | Example | Example | Example | Example |
|---|---|---|---|---|---|
| cation | Example 1 | 1-1 | 1-2 | 1-3 | 1-4 |
| ωₘₐₓ(Hz) | 25.1 | 25.1 | 20.0 | 20.0 | 20.0 |
| tₑ(ms) | 6.34 | 6.34 | 7.96 | 7.96 | 7.96 |

FIG. 4 shows the Niquist plot, the fₘₐₓ value by concentrations, and the lifetime of electrons depending on the concentration of APS with which the TiO₂ photoelectrode is coated. The leftmost empty part in the Niquist plot represents the resistance of the counter electrode FTO, the first semi-circular part on the left side represents the impedance at the counter electrode/electrolyte interface, the second semi-circular part represents the impedance at the TiO₂/electrolyte interface, and the third semi-circular part represents the impedance of the electrolyte. Here, the lifetime of electrons τₑ in the TiO₂ photoelectrode can be calculated through the following expression using the frequency value fₘₐₓ of the highest part in the second semi-circular part.

$${τ}_{e} = \frac{1}{{ω}_{max}} = \frac{1}{2 π {f}_{max}}$$

It can be seen from this expression that the lifetime of electrons in the TiO₂ photoelectrode becomes longer as the frequency value fₘₐₓ of the highest part in the second semi-circular part becomes smaller. Since a TiO₂ particle in the basic dye-sensitized solar cell is coated with a unimolecular dye polymer, the TiO₂ particles should not ideally come in contact with the electrolyte. However, the surfaces of all the TiO₂ particles are not practically covered with the dye polymer and thus many surfaces come in direct contact with the electrolyte. However, when the surface of the TiO₂ photoelectrode is coated with the APS in a core-shell structure as in Examples 1-1 to 1-4, the area of the surface of the TiO₂ photoelectrode coming in contact with the electrolyte can be more reduced than the electrode not coated. Accordingly, since the APS serves to lower the recombination probability between the TiO₂ photoelectrode and the electrolyte, the lifetime of electrons is elongated and the electron loss is reduced to enhance Jsc, thereby improving the photoelectric conversion efficiency.

### Experimental Example 3

### UV Spectrum

The UV spectra of the semiconductor electrode manufactured in Example 1-1 and the semiconductor electrode manufactured in Comparative Example 1 are measured and the results are shown in FIG. 5. As can be seen from FIG. 5, the variation in absorbance due to the coating with the APS does not appear in all the glass, the glass coated with the APS, the TiO₂, and the TiO₂ coated with the APS. Therefore, the coating with the APS does not influence the variation in transmittance.

### Experimental Example 4

### FT-IR Spectrum

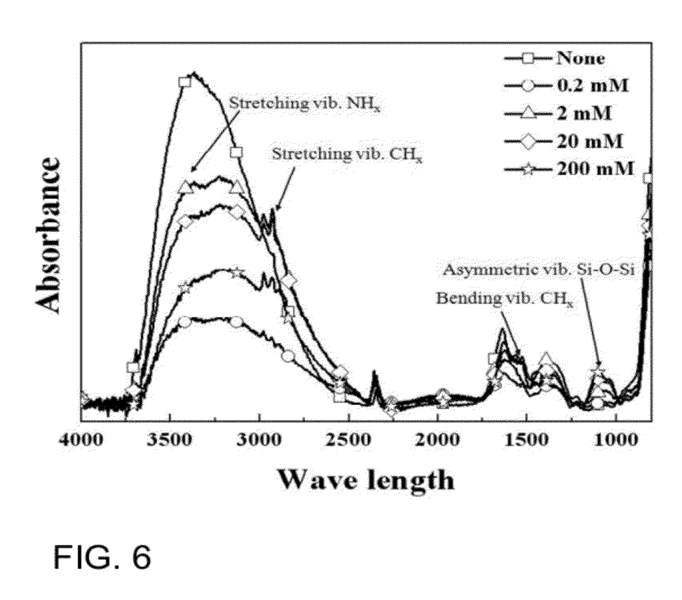

The FT-IR spectra of the semiconductor electrode manufactured in Example 1-1 and the semiconductor electrode manufactured in Comparative Example 1 are measured and the results are shown in FIG. 6. As can be seen from FIG. 6, the stretching vibration peak of the NHₓ and amine group, the stretching and bending vibration peaks of CHₓ, and the asymmetric vibration peak of Si—O—Si can be confirmed. The peaks appearing at about 2980 to 2850 cm⁻¹ are peaks associated with the stretching vibration of CHx and the absorption peaks appearing at 1690 cm⁻¹ are the absorption peaks representing the bending vibration peak of CHx. The N—H stretching vibration peak of —NH₂ is the absorption peak appearing at 3400 cm⁻¹ and the asymmetric vibration absorption peaks of Si—O—Si can be confirmed by the absorption peak appearing at 1100 cm⁻¹. It can be seen from the FT-IR spectra that the surface is coated with the APS when the TiO₂ photoelectrode is dipped in a toluene solution including the APS for 30 minutes.

### Experimental Example 5

### Transmission Electron Microscope Photograph

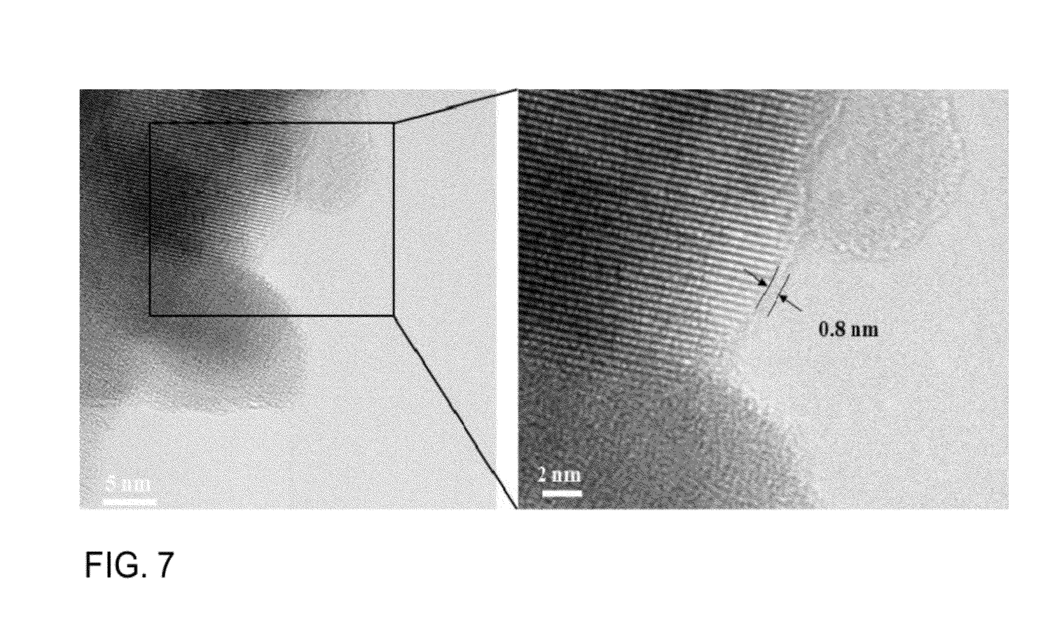

The semiconductor electrode manufactured in Example 1-3 is photographed with a transmission electron microscope (TEM) and the result is shown in FIG. 7. As can be seen from FIG. 7, a disordered film is formed on the crystalline TiO₂ surface. This is caused by coating TiO₂ with a polymer organic material and the TiO₂ surface is coated with the polymer organic material with a thickness of about 0.8 nm. Various functional groups of the APS are confirmed by measuring FT-IR spectra and the results are shown in FIG. 6.

### Experimental Example 6

### Depth Profile of TOF-SIMS by APS Concentrations

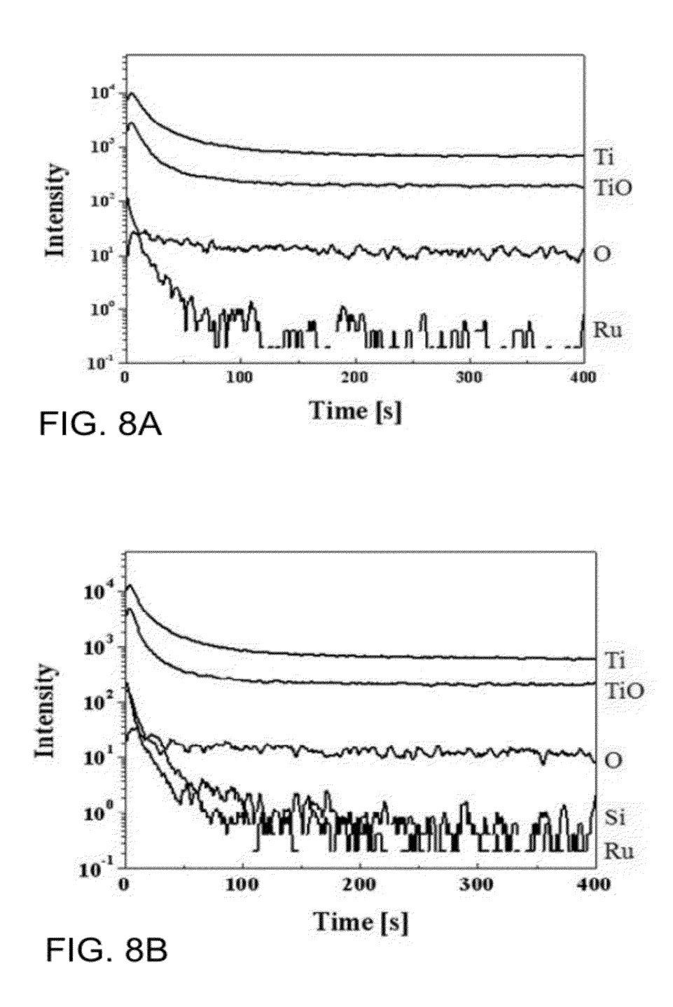

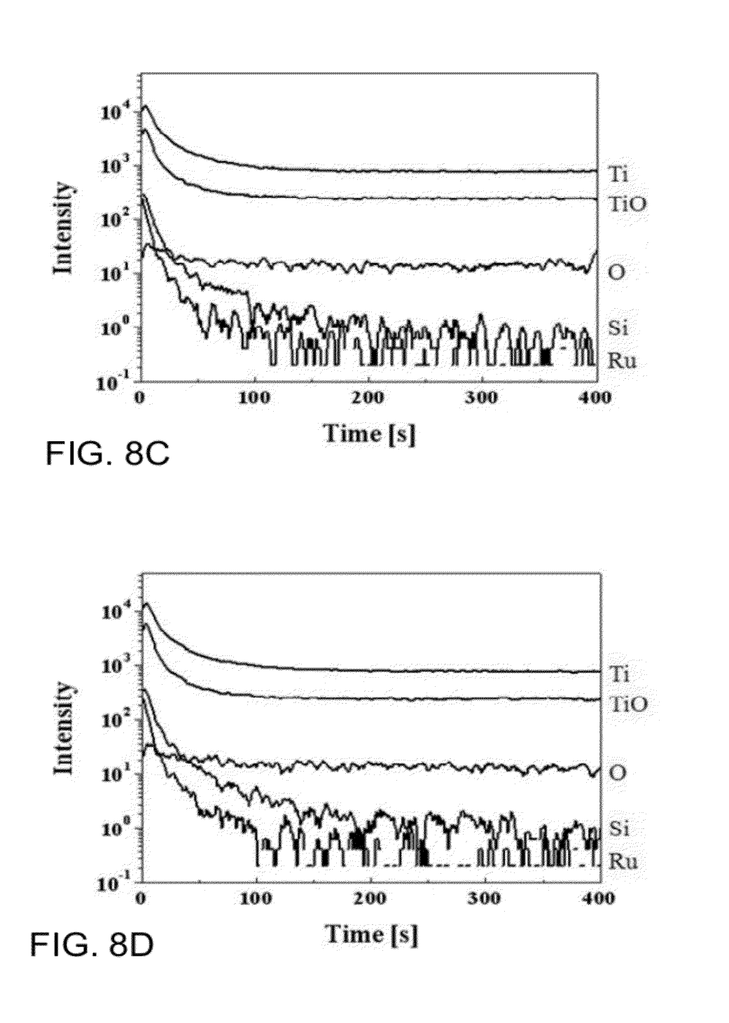

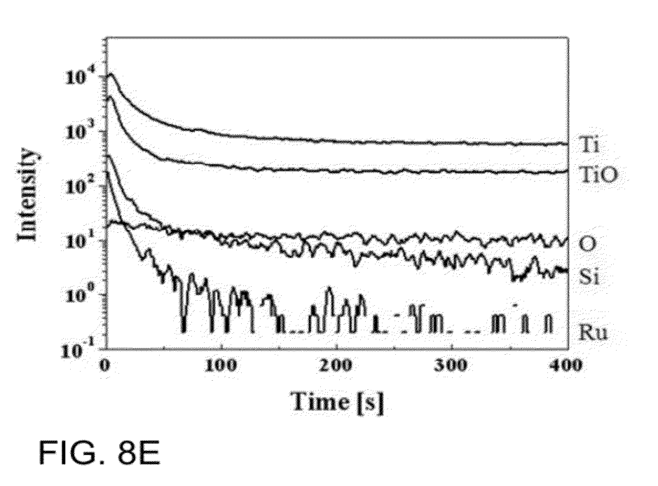

The depth curves of TOF-SIMS by APS concentrations are measured on the semiconductor electrodes manufactured in Examples 1-1 to 1-4 and Comparative Example 1 and are shown in FIGS. 8A to 8E. FIG. 8A corresponds to Comparative Example 1 and FIGS. 8B to 8E correspond to Examples 1-1 to 1-4. The degree of coating with the APS by concentrations can be checked by measuring the amount of silicon (Si) contained as a main component of the APS. On the basis of the fact that Si ions are most detected in Example 1-4, it can be seen that the amount of APS coated increases as the concentration increases.

What is claimed is:

1. A semiconductor electrode for a dye-sensitized solar cell comprising:
a conductive substrate;
a semiconductor oxide layer that is formed on the conductive substrate;
an organic layer with which the surface of the semiconductor oxide layer and the surface of the conductive substrate are coated in a core-shell structure; and
a dye that is adsorbed on the surface of the organic layer.

2. The semiconductor electrode for a dye-sensitized solar cell according to claim 1, wherein the conductive substrate is a glass substrate or a plastic substrate coated with indium tin oxide (ITO), fluorine-doped tin oxide (FTO), or carbon nano-tube (CNT).

3. The semiconductor electrode for a dye-sensitized solar cell according to claim 1, wherein the semiconductor oxide layer is formed in the form of nano-particle, nano-wire, or nano-tube.

4. The semiconductor electrode for a dye-sensitized solar cell according to claim 1, wherein the semiconductor oxide layer is formed of one or more selected from the group consisting of titanium oxide, tungsten oxide, niobium oxide, hafnium oxide, indium oxide, tin oxide, and zinc oxide.

5. The semiconductor electrode for a dye-sensitized solar cell according to claim 1, wherein the organic layer is formed of a silane compound.

6. The semiconductor electrode for a dye-sensitized solar cell according to claim 1, wherein the organic layer is formed of aminopropyltriethoxysilane (APS).

7. The semiconductor electrode for a dye-sensitized solar cell according to claim 1, wherein the dye is a ruthenium complex.

8. A dye-sensitized solar cell comprising:
the semiconductor electrode according to claim 1;
an electrolyte layer; and
a counter electrode.

9. A method of manufacturing a semiconductor electrode for a dye-sensitized solar cell, the method comprising:
(S1) forming a semiconductor oxide layer on a conductive substrate;
(S2) dipping the conductive substrate having the semiconductor oxide layer formed thereon in a solution including an organic material to coat the surface of the semiconductor oxide layer and the surface of the conductive substrate with an organic layer in a core-shell structure; and
(S3) adsorbing a dye on the organic layer through the use of an electrostatic attraction.

10. The method of manufacturing a semiconductor electrode for a dye-sensitized solar cell according to claim 9, wherein the semiconductor oxide layer is formed in the form of nano-particle, nano-wire, or nano-tube in S1.

11. The method of manufacturing a semiconductor electrode for a dye-sensitized solar cell according to claim 9, further comprising drying the conductive substrate having the semiconductor oxide layer formed thereon in the temperature range of 50° C. to 150° C. and then sintering the resultant in the temperature range of 100° C. to 1000° C. after S1.

12. The method of manufacturing a semiconductor electrode for a dye-sensitized solar cell according to claim 9, wherein the concentration of the organic material is controlled to enhance the efficiency of the dye-sensitized solar cell in S2.

13. The method of manufacturing a semiconductor electrode for a dye-sensitized solar cell according to claim 9, wherein when the organic material is aminopropyltriethoxysilane, the concentration of the organic material is in the range of 0.2 to 200 mM.

14. The method of manufacturing a semiconductor electrode for a dye-sensitized solar cell according to claim 9, wherein the conductive substrate is a glass substrate or a plastic substrate coated with indium tin oxide (ITO), fluorine-doped tin oxide (FTO), or carbon nano-tube (CNT).

15. The method of manufacturing a semiconductor electrode for a dye-sensitized solar cell according to claim 9, wherein the semiconductor oxide layer is formed of one or more selected from the group consisting of titanium oxide, tungsten oxide, niobium oxide, hafnium oxide, indium oxide, tin oxide, and zinc oxide.

16. The method of manufacturing a semiconductor electrode for a dye-sensitized solar cell according to claim 9, wherein the organic layer is formed of a silane compound.

17. The method of manufacturing a semiconductor electrode for a dye-sensitized solar cell according to claim 9, wherein the organic layer is formed of aminopropyltriethoxysilane (APS).

18. The method of manufacturing a semiconductor electrode for a dye-sensitized solar cell according to claim 9, wherein the dye is a ruthenium complex.
